(19) United States
(12) Patent Application Publication
(10) Pub. No.: US 2016/0068958 A1
(43) Pub. Date: Mar. 10, 2016

(54) Lamp Heater For Atomic Layer Deposition

(71) Applicants: Umesh M KELKAR, San Jose, CA (US); Kallol BERA, San Jose, CA (US); Karthik RAMANATHAN, Gate, Bangalore, Karnataka (IN); Garry K KWONG, San Jose, CA (US); Joseph YUDOVSKY, Campbell, CA (US); Applied Materials, Inc., Santa Clara, CA (US)

(72) Inventors: Umesh M. Kelkar, San Jose, CA (US); Kallol Bera, Fremont, CA (US); Karthik Ramanathan, Gate, Bangalore, Karnataka (IN); Garry K Kwong, San Jose, CA (US); Joseph Yudovsky, Campbell, CA (US)

(73) Assignee: Applied Materials, Inc., Santa Clara, CA (US)

(21) Appl. No.: 14/785,009

(22) PCT Filed: Apr. 10, 2014
(86) PCT No.: PCT/US14/33604

§ 371 Date: Oct. 16, 2015

Related U.S. Application Data
(60) Provisional application No. 61/812,507, filed on Apr. 16, 2013.

(51) Int. Cl. C23C 16/46; C23C 16/458; C23C 16/455

(52) U.S. Cl. CPC C23C 16/46; C23C 16/45544; C23C 16/4584

(57) ABSTRACT

Apparatus and methods for processing a plurality of semiconductor wafers on a susceptor assembly so that the temperature across the susceptor assembly is uniform are described. A plurality of linear lamps are positioned and controlled in zones to provide uniform heating.

### BACKGROUND

Embodiments of the invention generally relate to apparatus and methods for controlling the temperature of a substrate during processing. In particular, embodiments of the invention are directed to apparatus and methods incorporating linear lamps to uniformly control the temperature of a large susceptor assembly to control the temperature of a plurality of substrates.

Dielectric and metal film (e.g, SiN, SiCN, TiN) atomic layer deposition processes require high wafer temperatures (generally greater than or equal to about 500° C.). These process temperature cannot be achieved using resistive heaters. Use of graphite heaters to reach high temperature is expensive. Additionally, resistive heaters and graphite heaters can cause contamination of the processed films. The installation and replacement of resistive and graphite heaters can be complex, difficult and expensive.

Lamps which can be used to radiatively heat the wafer can achieve high temperatures at low cost. Lamps are easier to install and replace compared to resistive and graphite heaters. The ramp up of wafer temperature is much faster with lamp heating compared to resistive or graphite heating. However, in processing chambers using large susceptor assemblies, lamp heating is not uniform. This results in a temperature gradient across the susceptor assembly which results in film deposition non-uniformity.

Therefore, there is a need in the art for methods and apparatus capable of controlling wafer temperature on large susceptor assemblies.

### SUMMARY

One or more embodiments of the invention are directed to processing chambers comprising a gas distribution assembly and a susceptor assembly. The susceptor assembly is below the gas distribution assembly and has a disk-shape including a top surface and a bottom surface defining a thickness. The top surface of the susceptor assembly includes at least one recess surface to support a wafer. A drive shaft supporting the susceptor assembly to rotate the susceptor assembly. A plurality of linear lamps are positioned beneath the susceptor assembly. The plurality of linear lamps separated into a plurality of zones. A controller is connected to the plurality of linear lamps to provide power independently to each of the zones of linear lamps.

In some embodiments, the susceptor assembly is sized to support at least three wafers.

In one or more embodiments, the susceptor has a diameter in the range of about 0.75 m to about 2 m.

In some embodiments, the linear lamps are arranged in concentric circles about the drive shaft. In one or more embodiments, wherein each of the linear lamps are substantially the same length.

In some embodiments, the plurality of linear lamps are substantially parallel to each other and extend perpendicularly to a diameter of the susceptor assembly. In one or more embodiments, the plurality of linear lamps have at least two different lengths.

Some embodiments further comprise at least two u-shaped lamps positioned around the drive shaft. In one or more embodiments, the at least two u-shaped lamps are positioned around the drive shaft to have a two-fold symmetry about the drive shaft. In some embodiments, a curved portion of each of the two u-shaped lamps are adjacent the drive shaft. In some embodiments, at least two u-shaped lamps define a first zone.

In one or more embodiments, the linear lamps are separated into at least two zones. In some embodiments, the linear lamps are separated into a second zone, a third zone and a fourth zone, each zone positioned further from the drive shaft and on opposite sides thereof. In one or more embodiments, the second zone comprises two linear lamps having a first length extending perpendicular to a diameter of the susceptor assembly and spaced a first distance along the diameter from the drive shaft so that the second zone is on opposite sides of the first zone, the third zone comprising at least one linear lamps having a second length shorter than the first length, the third zone positioned a second distance along the diameter from the drive shaft greater than the first distance so that the third zone is on opposite sides of the second zone and the fourth zone includes at least one lamp having the second length and/or at least one lamp having a third length shorter than the second length, the fourth zone positioned a third distance along the diameter from the drive shaft greater than the second distance so that the fourth zone is on opposite sides of the third zone.

In some embodiments, each of the linear lamps has an electrode at least one end of the lamp, the electrode bends downward away from the bottom surface of the susceptor assembly.

In one or more embodiments, the linear lamps include a reflective surface along a lower portion of the lamp to reflect light from the lamp toward the bottom surface of the susceptor assembly.

Additional embodiments of the invention are directed to processing chambers comprising a gas distribution assembly and a susceptor assembly. The susceptor assembly is below the gas distribution assembly and has a disk-shape including a top surface and a bottom surface defining a thickness. The top surface including at least one recess surface to support a wafer. A drive shaft supports the susceptor assembly to rotate the susceptor assembly. A plurality of linear lamps are positioned beneath the susceptor assembly. The plurality of linear lamps are separated into at least two zones and extend parallel to each other and perpendicular to a diameter of the susceptor assembly. At least two u-shaped lamps are positioned around the drive shaft to have two-fold symmetry about the drive shaft. A controller is connected to the plurality of linear lamps to provide power independently to each of the zones of linear lamps.

In some embodiments, the at least two u-shaped lamps define a first zone. In one or more embodiments, the linear lamps are separated into a second zone, a third zone and a fourth zone, each zone positioned further from the drive shaft and on opposite sides thereof. In some embodiments, the second zone comprises two linear lamps having a first length, the linear lamps extending perpendicular to a diameter of the susceptor assembly and spaced a first distance along the diameter from the drive shaft so that the second zone is on opposite sides of the first zone, the third zone comprising at least one linear lamps having a second length shorter than the first length, the third zone positioned a second distance along the diameter from the drive shaft greater than the first distance so that the third zone is on opposite sides of the second zone and the fourth zone includes at least one lamp having the second length and/or at least one lamp having a third length shorter than the second length, the fourth zone positioned a third distance along the diameter from the drive shaft greater than the second distance so that the fourth zone is on opposite sides of the third zone.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows partial cross-sectional view of a processing chamber in accordance with one or more embodiment of the invention; and

FIG. 2 shows a view of a portion of a gas distribution assembly in accordance with one or more embodiment of the invention;

FIG. 3 shows a cross-sectional view of a lamp assembly in accordance with one or more embodiment of the invention;

FIG. 4 shows a perspective view of a lamp assembly in accordance with one or more embodiment of the invention;

FIG. 5 shows a cross-sectional view of a lamp assembly in accordance with one or more embodiment of the invention;

FIG. 6 shows a cross-sectional view of a lamp assembly in accordance with one or more embodiment of the invention;

FIG. 7 shows a cross-sectional view of a lamp assembly in accordance with one or more embodiment of the invention;

FIG. 8 shows a cross-sectional view of a single lamp in accordance with one or more embodiment of the invention;

FIG. 9 shows a cross-sectional view of a lamp assembly in accordance with one or more embodiment of the invention; and

FIG. 10 shows a graph of temperature as a function of radial distance from the center of the susceptor assembly in accordance with one or more embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention are directed to apparatus and methods for creating a differential pressure developed from a unique precursor injector design with a magnitude sufficient to hold wafers in place at high rotation speeds. As used in this specification and the appended claims, the terms “wafer”, “substrate” and the like are used interchangeably. In some embodiments, the wafer is a rigid, discrete substrate.

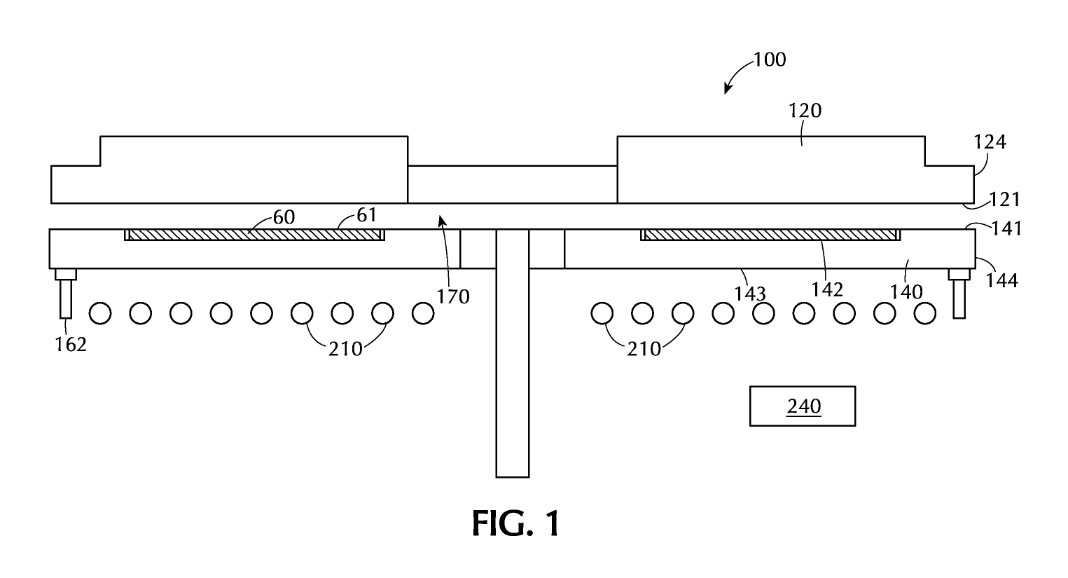

FIG. 1 shows cross-section of a processing chamber 100 including a gas distribution assembly 120, also referred to as injectors or an injector assembly, and a susceptor assembly 140. The gas distribution assembly 120 is any type of gas delivery device used in a processing chamber. The gas distribution assembly 120 includes a front surface 121 which faces the susceptor assembly 140. The front surface 121 can have any number or variety of openings to deliver a flow of gases toward the susceptor assembly 140. The gas distribution assembly 120 also includes an outer edge 124 which, in the embodiments, shown, is substantially round.

The specific type of gas distribution assembly 120 used can vary depending on the particular process being used. Embodiments of the invention can be used with any type of processing system where the gap between the susceptor and the gas distribution assembly is controlled. While various types of gas distribution assemblies can be employed (e.g., showerheads), embodiments of the invention may be particularly useful with spatial ALD gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. The plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the processing region through the purge gas P channel(s). A substrate moving from one end of the gas distribution assembly to the other end will be exposed to each of the process gases in turn, thereby forming a layer on the substrate surface.

In some embodiments, the gas distribution assembly 120 is a rigid stationary body made of a single injector unit. In one or more embodiments, the gas distribution assembly 120 is made up of a plurality of individual sectors 122. A gas distribution assembly having either a single piece body or a multi-sector body can be used with the various embodiments of the invention described.

The susceptor assembly 140 is positioned beneath the gas distribution assembly 120. The susceptor assembly 140 includes an edge 144, a top surface 141 and a bottom surface 143 defining a thickness. The top surface 141 can include at least one recess 142 sized to support a substrate for processing. The recess 142 can be any suitable shape and size depending on the shape and size of the wafers 60 being processed. In the embodiment shown in FIG. 1, the recess 142 has a flat bottom to support the bottom of the wafer, but it will be understood that the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 1, the recess 142 in the top surface 141 of the susceptor assembly 140 is sized so that a wafer 60 supported in the recess 142 has a top surface 61 substantially coplanar with the top surface 141 of the susceptor 140. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 140 of FIG. 1 includes a drive shaft 160 which is capable of lifting, lowering and rotating the susceptor assembly 140. The susceptor assembly may include a heater, or gas lines, or electrical components within the center of the support post 160. The support post 160 may be the primary means of increasing or decreasing the gap between the susceptor assembly 140 and the gas distribution assembly 120. The susceptor assembly 140 may also include fine tuning actuators 162 which can make micro-adjustments to susceptor assembly 140 to create a desired gap 170 between the susceptor assembly 140 and the gas injector assembly 120.

In some embodiments, the gap 170 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

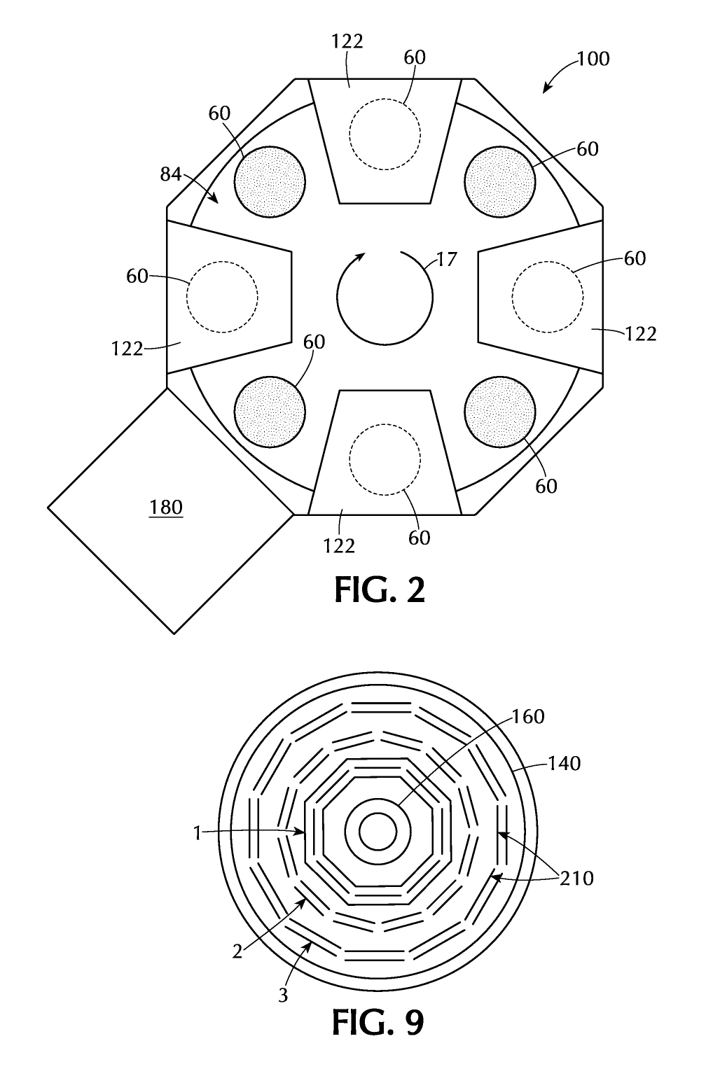

The processing chamber 100 shown in the Figures is a carousel-type chamber in which the susceptor assembly 140 can hold a plurality of wafers 60. As shown in FIG. 2, the gas distribution assembly 120 may include a plurality of separate injector units 122, each injector unit 122 being capable of depositing a film on the wafer, as the wafer is moved beneath the injector unit. Four generally pie-shaped injector units 122 are shown positioned on approximately opposite sides of and above the susceptor assembly 140. This number of injector units 122 is shown for illustrative purposes only. It will be understood that more or less injector units 122 can be included. In some embodiments, there are a sufficient number of pie-shaped injector units 122 to form a shape conforming to the shape of the susceptor assembly 140. In some embodiments, each of the individual pie-shaped injector units 122 may be independently moved, removed and/or replaced without affecting any of the other injector units 122. For example, one segment may be raised to permit a robot to access the region between the susceptor assembly 140 and gas distribution assembly 120 to load/unload wafers 60.

Similarly, although not shown, the susceptor assembly 140 can be made up of a plurality of separately pieces or units. The plurality of units can be generally pie shaped and can be fitted together to form a susceptor assembly having a top surface and bottom surface.

The size of the susceptor assembly 140 can be varied depending on the specific processing chamber and the size of the wafers to be processed. In some embodiments, the susceptor assembly is sized to support at least three wafers. In one or more embodiments, the susceptor assembly is sized to support at least 3, 4, 5, 6, 7, 8, 9, 10, 11, 12, 13, 14, 15, 16 or more wafers. The wafers can be any size wafer including, but not limited to, 150 mm, 200 mm, 300 mm and 450 mm wafers. The diameter of the susceptor assembly can also vary. In some embodiments, the susceptor assembly has a diameter in the range of about 0.75 meters to about 2 meters, or in the range of about 1 meter to about 1.75 meters of in the range of about 1.25 meters to about 1.75 meters or about 1.5 meters.

Processing chambers having multiple gas injectors can be used to process multiple wafers simultaneously so that the wafers experience the same process flow. For example, as shown in FIG. 2, the processing chamber 100 has four gas injector units 122 and four wafers 60. The drawing of four injector units 122 is merely representative and is chosen to allow easier view and description of the process. Those skilled in the art will understand that the gas distribution assembly can be a single component and can be approximately the same size and/or shape as the susceptor assembly. At the outset of processing, the wafers 60 can be positioned between the injector units 122. Rotating 17 the susceptor assembly 140 by 45° will result in each wafer 60, which is between injector units 122 to be moved to an injector units 122 for film deposition, as illustrated by the dotted circle under the injector assemblies 122. An additional 45° rotation would move the wafers 60 away from the injector assemblies 30. With spatial ALD injectors, a film is deposited on the wafer during movement of the wafer relative to the injector assembly. In some embodiments, the susceptor assembly 140 is rotated in increments that prevent the wafers 60 from stop beneath the injector units 122. The number of wafers 60 and injector units 122 can be the same or different. In some embodiments, there are the same number of wafers being processed as there are gas distribution assemblies. In one or more embodiments, the number of wafers being processed are fraction of or an integer multiple of the number of gas distribution assemblies. For example, if there are four gas distribution assemblies, there are 4× wafers being processed, where x is an integer value greater than or equal to one.

The processing chamber 100 shown in FIG. 2 is merely representative of one possible configuration and should not be taken as limiting the scope of the invention. Here, the processing chamber 100 includes a plurality of gas distribution assemblies 120. In the embodiment shown, there are four gas distribution assemblies 30 evenly spaced about the processing chamber 100. The processing chamber 100 shown is octagonal, however, it will be understood by those skilled in the art that this is one possible shape and should not be taken as limiting the scope of the invention. The gas distribution assemblies 120 shown are trapezoidal, but it will be understood by those skilled in the art that the gas distribution assemblies can be a single circular component or made up of a plurality of pie-shaped segments having radiused inner and/or outer peripheral edges.

The embodiment shown in FIG. 2 includes a load lock chamber 180, or an auxiliary chamber like a buffer station. This chamber 180 is connected to a side of the processing chamber 100 to allow, for example, the substrates 60 to be loaded/unloaded from the chamber 100. A wafer robot may be positioned in the chamber 180 to move the substrate

Rotation of the carousel (e.g., the susceptor assembly 140) can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

Referring back to FIG. 1, the processing chamber 100 includes a plurality of lamps 210 positioned beneath the susceptor assembly 140. As the susceptor assembly 140 can move closer to or further from the gas distribution assembly 120, the distance between the susceptor assembly 140 and the plurality of lamps 210 may change. In some embodiments, the distance between the lamps 210 and susceptor assembly 140 remains substantially the same when the susceptor assembly is in the loading position (i.e., moved further from the gas distribution assembly) as when the susceptor assembly is in the processing position close to the susceptor assembly. In some embodiments, the lamps 210 are in fixed position and movement of the susceptor assembly between the loading to processing positions results in a change in the distance between the lamps and susceptor assembly.

The plurality of lamps 210 are linear lamps with spacing and zoning. As used in this specification and the appended claims, the term “linear lamp” means that the lamp is intended to be linear but that slight variations in the linearity are acceptable. For example, “linear lamps” may deviate from linearity by less than about 10%, 5%, 2% or 1%. The lamps, and processing chamber, are connected to a controller 240 which can independently control the susceptor assembly, gas distribution assembly, lamps and/or zones of lamps.

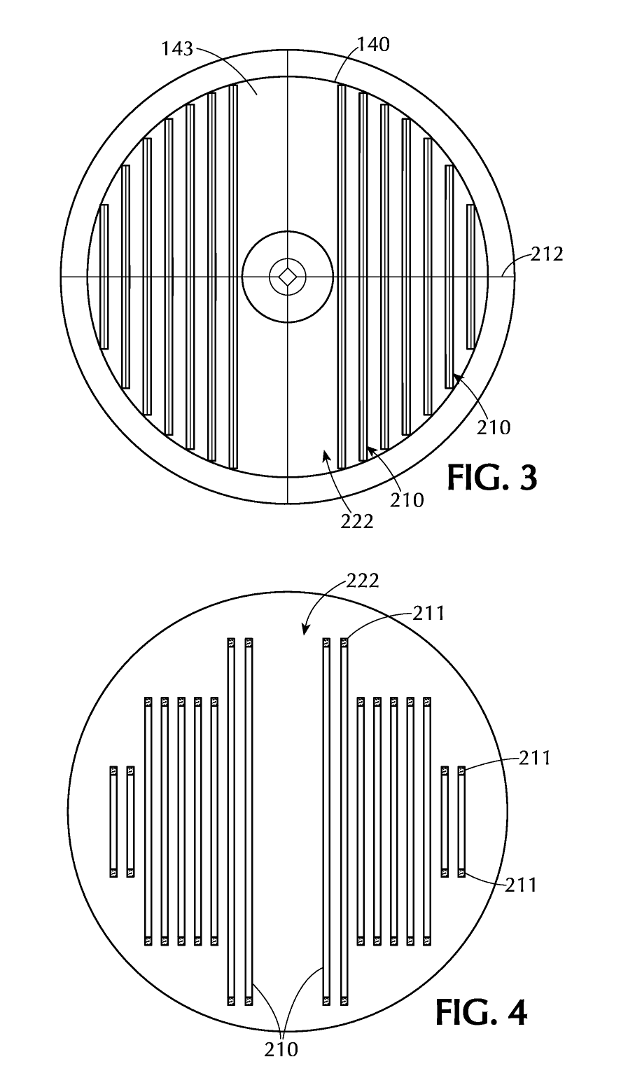

FIG. 3 shows an embodiment of a susceptor assembly 140 with a plurality of lamps 210 which are spaced apart and substantially parallel to each other. The lamps have terminals 211, also called electrodes in shown FIG. 4, at either end near the edge of the processing chamber. As used in this specification and the appended claims, the term “substantially parallel” means that the lamps are parallel within a reasonable amount. There can be slight variations in the parallelism of the lamps and still fall within the scope of “substantially parallel”. For example, substantially parallel lamps have a distance between the lamps which does not vary by more than 10%, 5%, 2% or 1% along the entire length of the lamps.

Each of the lamps 210 are parallel to each other and extend perpendicularly to a diameter 212 of the susceptor assembly. The diameter 212 is not an actual line, but merely a representation of a diameter. Those skilled in the art will understand that the lamps are spaced, for example, at increasing distances from the center of the susceptor assembly, where the drive shaft 160 is located.

The spacing between the lamps can vary or can be substantially the same. In some embodiments, the lamps are spaced in the range of about 15 mm to about 75 mm apart, or in the range of about 20 mm to about 70 mm apart, or in the range of about 25 mm to about 65 mm apart, or in the range of about 30 mm to about 60 mm apart, or in the range of about 35 mm to about 55 mm apart, or in the range of about 40 mm to about 50 mm apart.

Each of the lamps 210 in FIG. 3 has a different length. The lamps extend between regions near the outer peripheral edges of the susceptor assembly across the diameter 212 to a region near the outer peripheral edge on the other side. As the lamps are positioned along the diameter but further from the drive shaft, the distance between the peripheral edge regions decreases. This results in each lamp on one side of the drive shaft having a different length. The length of the lamps on the other side of the drive shaft can be mirror images or different lengths as well. This can result in the need for a large number of possible lamp sizes.

Radiation from the lamps heat up the susceptor, and therefore, the wafer sitting on the susceptor. The wafers can reach a processing temperature greater than about 500° C. The lamp filaments reach much higher temperature, generally greater than about 1800° C. As the susceptor assembly rotates, the azimuthal temperature (temperature when susceptor assembly is stationary) variations are blended with the surrounding areas resulting in a radial temperature profile. The radial temperature profile can be modified and made more uniform by controlling the lamps in zones, instead of as a whole group.

Referring to FIG. 4, some embodiments separate the lamps into discrete lengths. For example, there can be two, three, four, five, six or more discrete lamp lengths used to heat the susceptor assembly. The embodiment of FIG. 4 has three different lamp lengths. This would mean that only three different part numbers would need to be ordered to have an entire collection of replacement lamps.

The lamps 210 shown in FIG. 4 have terminals 211 near cold regions, relative to the center, in the processing chamber. This allows the electrical connections to the electronics to be maintained with less possibility of overheating than if the terminals were in a hotter region.

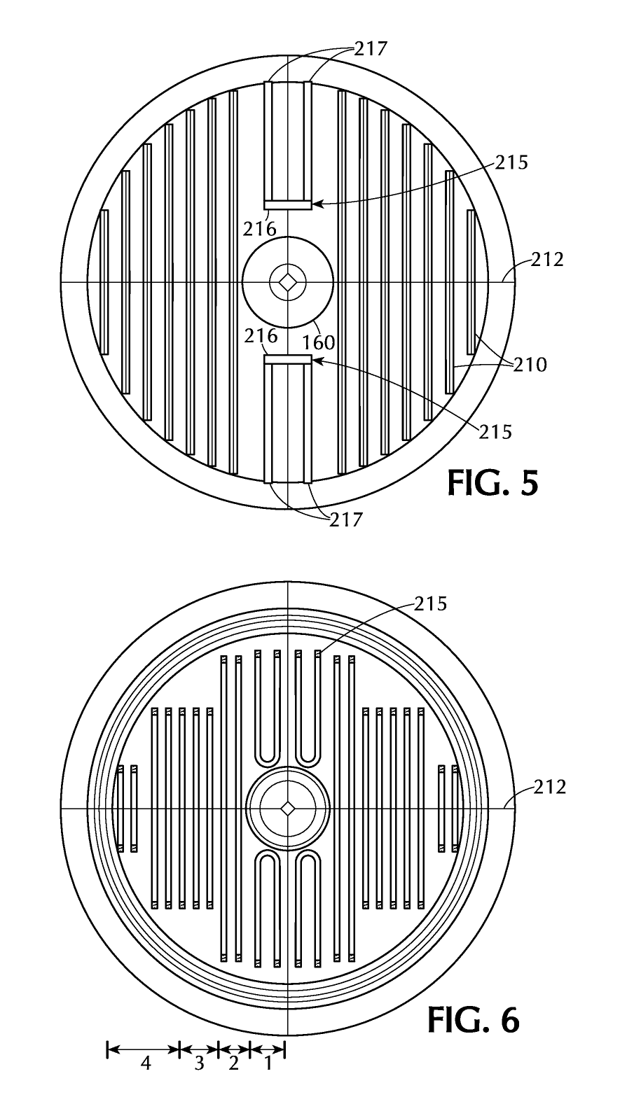

There is a central region 222 which has no lamps 210. However, in some embodiments it may be desirable to include one or more lamps in this central region 222. Referring to FIG. 5, at least two u-shaped lamps 215 are positioned in the central region 222. These lamps have a curved or straight section 216 and terminals 217. The curved section can be placed near the drive shaft 160 so that terminals 217 can be located at the outer cooler region of the processing chamber. However, in some embodiments, the direction of the u-shaped lamp 215 is reversed so that the terminals 217 are near the drive shaft 160 and the curved section 216 near the outer edge of the susceptor assembly.

The u-shaped lamps 215 shown in FIG. 5 are positioned at the same distance along the diameter 212 from the drive shaft 160. Here, the center of the lamp curved section 216 is even with the center of the diameter 212. However, there can be more than two u-shaped lamps and the positioning can vary. In some embodiments, as shown in FIG. 6, there are four u-shaped lamps positioned around the drive shaft 160. The positioning of the lamps 210 is such that there is two-fold symmetry of the lamps 210 about the drive shaft 160. This is also true for the embodiment shown in FIG. 5.

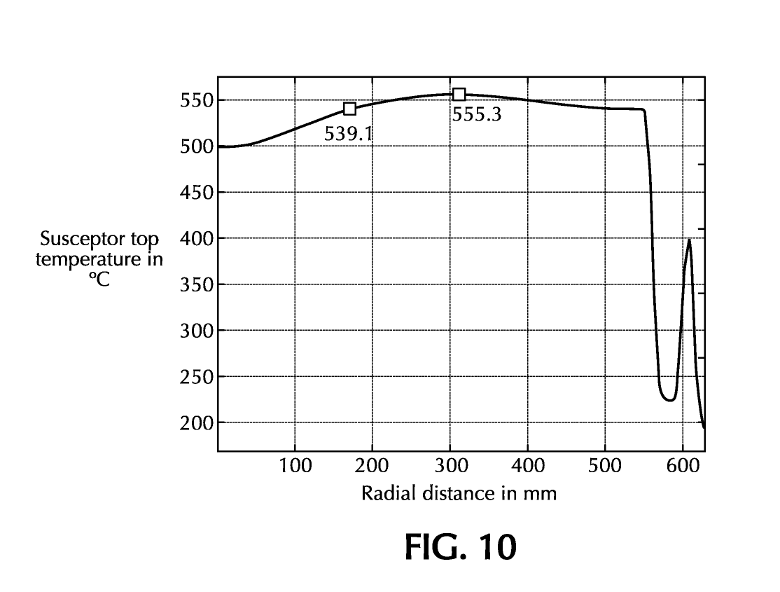

FIG. 6 shows a four zone embodiment of the invention. Here, the at least two u-shaped lamps 215 define a first zone 1. The linear lamps 210 are separated into a second zone 2, a third zone 3 and a fourth zone 4. Each zone is positioned further from the drive shaft 160 and on opposite sides of the drive shaft 160. In the embodiment shown, the second zone 2 comprises two linear lamps 210 having a first length. There are two second zones 2 with one on each of the left side and right side of the drive shaft 160. The two second zones 2 are spaced a first distance from the center of the diameter 212. The third zone 3 comprises at least three linear lamps 210 having a second length which is shorter than the first length. The third zones are positioned a second distance from the center of the diameter 212 which is greater than the first distance. Each of the two third zones 3 are on opposite sides of the drive shaft 160 and on opposite sides of the first and second zones. The further zone 4 includes at least one lamp 210 having the second length and at least one lamp 210 having a third length shorter than the second length. The fourth zone 4 is positioned a third distance along the diameter 212 from the drive shaft 160 which is greater than the second distance so that the fourth zone 4 is on opposite sides of the third zone from the second zone and drive shaft 160. Temperature can be measured in the wafer region of the susceptor assembly using any suitable measurement device including, but not limited to thermocouples and pyrometers. For average wafer temperature of ˜500° C., temperature non-uniformity across the wafer of less than about 20° C. is acceptable. As the wafer process temperature is lowered, the acceptable temperature non-uniformity across the wafer may also be lowered (i.e., stricter control of the temperature is required). FIG. 10 shows a graph of the temperature of the susceptor/wafer surface across the susceptor assembly in accordance with one or more embodiments of the invention. This graph shows the surface temperature as a function of the distance from the center of the susceptor assembly. This region includes the drive shaft and outer portion of the susceptor assembly. The marked locations indicate point of maximum and minimum temperature across the wafer (not the entire susceptor assembly). The difference in temperatures at these points is a measure of the temperature uniformity, which is about 16° C. here.

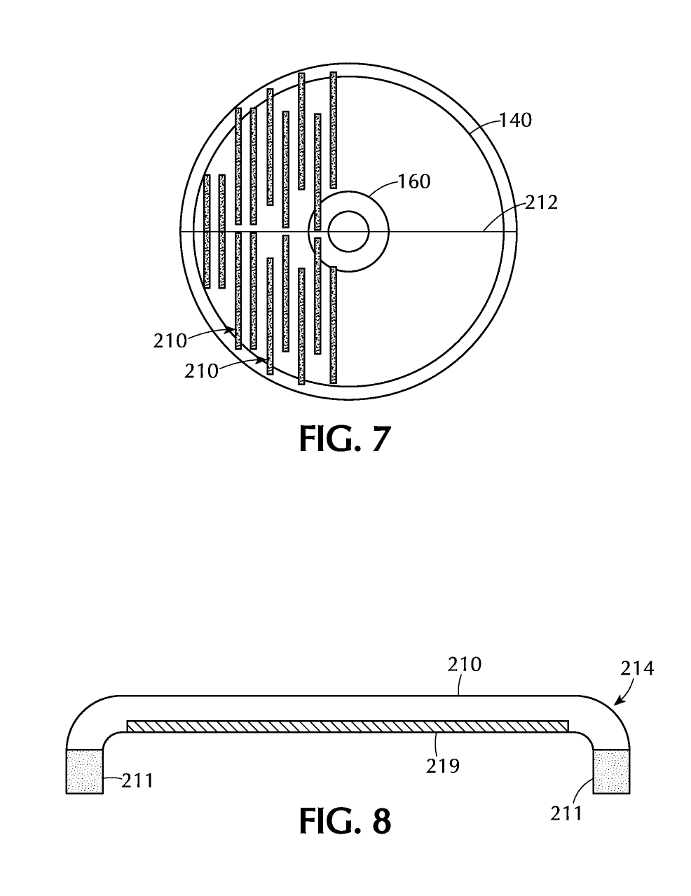

FIG. 7 shows another embodiment in which each of the linear lamps 210 have the same length. Each set of lamps 210 here are positioned at different distances from the diameter 212 and form a mirror image relative to the diameter 212. While these are shown as mirror images, it will be understood that they can be completely staggered as well. The right side of the Figure can be a mirror image of the left side so that the lamps cover the entire susceptor assembly 140. The lamp leads are no longer positioned at cooler part of the chamber for each of the lamps 210. Therefore, it may be desirable to have a different configuration for the electrodes. FIG. 8 shows such a configuration. Here, the linear lamps 210 have an electrode 211 on one or both ends of the lamp which bend 214 downward away from the bottom surface of the susceptor assembly. This allows the electrodes 211 to be moved away from the hottest portion of the susceptor assembly to minimize thermal damage and prolong the life of the lamp.

In some embodiments, the lamp 210 includes a reflective surface 219 along a lower portion of the lamp 210. The reflective surface 219 can reflect light from the lamp toward the bottom surface of the susceptor assembly. Additionally, the reflective surface 219 can help prevent the electrodes 211 from overheating by decreasing the amount of radiant energy impacting the electrodes. Suitable reflective surfaces include, but are not limited to, silver, gold, Al₂O₃, SiO₂ and combinations thereof.

FIG. 9 shows another embodiment of the invention in which the linear lamps 210 are arranged in concentric circles about the drive shaft 160. Here, there are three concentric circles which can make up the first zone 1, the second zone 2 and the third zone 3. In some embodiments, each of the linear lamps 210 are substantially the same length so that any lamp could be positioned at any point along the circles. As used in this specification an the appended claims, the term “substantially the same length” means that the length of the lamps are within the normal tolerances required for a lamp to be positioned in a fixed lamp holder so that there is sufficient electrical contact with the electrodes. In some embodiments, the lamps have a curved end like that shown in FIG. 8 to prevent overheating of the electrodes by moving the electrode further from the bottom surface of the susceptor assembly.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm or 450 mm diameter silicon wafer.

As used in this specification and the appended claims, the terms “reactive gas”, “reactive precursor”, “first precursor”, “second precursor” and the like, refer to gases and gaseous species capable of reacting with a substrate surface or a layer on the substrate surface.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A processing chamber comprising:
a gas distribution assembly;
a susceptor assembly below the gas distribution assembly, the susceptor assembly having a disk-shape including a top surface and a bottom surface defining a thickness, the top surface including at least one recess surface to support a wafer;
a drive shaft supporting the susceptor assembly to rotate the susceptor assembly;
a plurality of linear lamps positioned beneath the susceptor assembly, the plurality of linear lamps separated into a plurality of zones; and
a controller connected to the plurality of linear lamps to provide power independently to each of the zones of linear lamps.

2. The processing chamber of claim 1, wherein the susceptor assembly is sized to support at least three wafers.

3. The processing chamber of claim 1, wherein the susceptor has a diameter in the range of about 0.75 m to about 2 m.

4. The processing chamber of claim 1, wherein the linear lamps are arranged in concentric circles about the drive shaft.

5. The processing chamber of claim 4, wherein each of the linear lamps are substantially the same length.

6. The processing chamber of claim 1, wherein the plurality of linear lamps are substantially parallel to each other and extend perpendicularly to a diameter of the susceptor assembly.

7. The processing chamber of claim 6, wherein the plurality of linear lamps have at least two different lengths.

8. The processing chamber of claim 6, further comprising at least two u-shaped lamps positioned around the drive shaft and optionally having two-fold symmetry about the drive shaft.

9. The processing chamber of claim 1, wherein each of the linear lamps has an electrode on at least one end of the lamp, the electrode bending downward away from the bottom surface of the susceptor assembly.

10. The processing chamber claim 1, wherein the linear lamps include a reflective surface along a lower portion of the lamp to reflect light from the lamp toward the bottom surface of the susceptor assembly.

11. A processing chamber comprising:
a gas distribution assembly;
a susceptor assembly below the gas distribution assembly, the susceptor assembly having a disk-shape including a top surface and a bottom surface defining a thickness, the top surface including at least one recess surface to support a wafer;
a drive shaft supporting the susceptor assembly to rotate the susceptor assembly;
a plurality of linear lamps positioned beneath the susceptor assembly, the plurality of linear lamps separated into at least two zones, the plurality of lamps extending parallel to each other and perpendicular to a diameter of the susceptor assembly;
at least two u-shaped lamps positioned around the drive shaft to have two-fold symmetry about the drive shaft; and
a controller connected to the plurality of linear lamps to provide power independently to each of the zones of linear lamps.

12. The processing chamber of claim 11, wherein the at least two u-shaped lamps define a first zone.

13. The processing chamber of claim 12, wherein the linear lamps are separated into at least two zones.

14. The processing chamber of claim 12, wherein the linear lamps are separated into a second zone, a third zone and a fourth zone, each zone positioned further from the drive shaft and on opposite sides thereof.

15. The processing chamber of claim 14, wherein the second zone comprises two linear lamps having a first length, the linear lamps extending perpendicular to a diameter of the susceptor assembly and spaced a first distance along the diameter from the drive shaft so that the second zone is on opposite sides of the first zone, the third zone comprising at least one linear lamps having a second length shorter than the first length, the third zone positioned a second distance along the diameter from the drive shaft greater than the first distance so that the third zone is on opposite sides of the second zone and the fourth zone includes at least one lamp having the second length and/or at least one lamp having a third length shorter than the second length, the fourth zone positioned a third distance along the diameter from the drive shaft greater than the second distance so that the fourth zone is on opposite sides of the third zone.

16. The processing chamber of claim 9, wherein a curved portion of each of the two u-shaped lamps are adjacent the drive shaft.

17. The processing chamber of claim 9, wherein the at least two u-shaped lamps define a first zone.

18. The processing chamber of claim 17, wherein the linear lamps are separated into at least two zones.

19. The processing chamber of claim 18, wherein the linear lamps are separated into a second zone, a third zone and a fourth zone, each zone positioned further from the drive shaft and on opposite sides thereof.

20. A processing chamber comprising:
a gas distribution assembly;
a susceptor assembly below the gas distribution assembly, the susceptor assembly having a disk-shape including a top surface and a bottom surface defining a thickness, the top surface including at least one recess sized to support a wafer;
a drive shaft supporting the susceptor assembly to rotate the susceptor assembly;
at least two u-shaped lamps positioned around the drive shaft to have two-fold symmetry about the drive shaft, the at least two u-shaped lamps defining a first zone;
a plurality of linear lamps positioned beneath the susceptor assembly, the plurality of linear lamps separated into a second zone, a third zone and a fourth zone, the second zone comprising two linear lamps having a first length, the linear lamps extending perpendicular to a diameter of the susceptor assembly and spaced a first distance along the diameter from the drive shaft so that the second zone is on opposite sides of the first zone, the third zone comprising at least one linear lamps having a second length shorter than the first length, the third zone positioned a second distance along the diameter from the drive shaft greater than the first distance so that the third zone is on opposite sides of the second zone and the fourth zone includes at least one lamp having the second length and/or at least one lamp having a third length shorter than the second length, the fourth zone positioned a third distance along the diameter from the drive shaft greater than the second distance so that the fourth zone is on opposite sides of the third zone; and
a controller connected to the plurality of linear lamps to provide power independently to each of the zones of linear lamps.
